(19) United States
(12) Patent Application Publication
(10) Pub. No.: US 2019/0123304 A1
(43) Pub. Date: Apr. 25, 2019

(54) REFLECTIVE DISPLAY DEVICE

(71) Applicant: BOE TECHNOLOGY GROUP CO., LTD., Beijing (CN)

(72) Inventor: Zhen Liu, Beijing (CN)

(73) Assignee: BOE TECHNOLOGY GROUP CO., LTD., Beijing (CN)

(21) Appl. No.: 16/016,839

(22) Filed: Jun. 25, 2018

(30) Foreign Application Priority Data
Oct. 20, 2017 (CN) 201710985301.8

(51) Int. Cl. H01L 51/52; H01L 51/56; G06F 3/041; H01L 27/32; H01L 27/12; H01L 51/50

(52) U.S. Cl. CPC H01L 51/5271; H01L 51/56; G06F 3/0412; H01L 27/3213; H01L 27/3262; H01L 2251/5315; H01L 51/5206; H01L 51/5221; H01L 51/5284; H01L 51/5036; H01L 27/1214

(57) ABSTRACT

A reflective display device includes a reflective display panel and a white organic light-emitting diode (WOLED) front light source at a light emitting side of the reflective display panel. The WOLED front light source is a single-sided light emitting component, and a light emitting side of the WOLED front light source is oriented towards the reflective display panel.

### CROSS-REFERENCE TO RELATED APPLICATION

This application is based on and claims priority of Chinese Patent Application No. 201710985301.8, filed on Oct. 20, 2017, which is incorporated herein by reference in its entirety.

### TECHNICAL FIELD

The present disclosure relates to the field of display technologies, and in particular to a reflective display device.

### BACKGROUND

Reflective display technologies such as reflective liquid crystal display (LCD), electronic ink (E-ink), electrochromic display (ECD) and Mirasol display technologies, attract more and more attention in the field of wearable display due to their advantages of good outdoor readability and low power consumption. However, images displayed on these display devices cannot be seen in an environment with low ambient light or in a dark environment, which limits application scenarios of these display devices to a certain extent.

In the related art, a front light source in form of light guide plate structure may be added to these reflective display devices, to solve the problem that images cannot be seen in an environment with low ambient light or in a dark environment. However, since light emits from two sides of the front light source in form of light guide plate structure, these display devices have a very low contrast in the dark environment, generally less than 10:1, and thus the display effect is still difficult to meet requirements.

### SUMMARY

The present disclosure provides a reflective display device, which includes a reflective display panel and a white organic light-emitting diode (WOLED) front light source at a light emitting side of the reflective display panel. The WOLED front light source is a single-sided light emitting component, and a light emitting side of the WOLED front light source is oriented towards the reflective display panel.

Optionally, the WOLED front light source includes a base substrate, a first electrode layer, a light emitting layer and a second electrode layer; the first electrode layer, the light emitting layer and the second electrode layer are disposed on the base substrate. Orthographic projections of parts of the first electrode layer, the light emitting layer and the second electrode layer to the base substrate completely overlap each other, and these parts of the first electrode layer, the light emitting layer and the second electrode layer together from a light emitting unit.

Optionally, the light emitting unit is a grid-like structure, and the grid-like light emitting unit defines a plurality of light transmission regions.

Optionally, each of the light transmission regions has a square shape or a rectangular shape.

Optionally, each of the light transmission regions has a diamond shape.

Optionally, the WOLED front light source further includes a black matrix on the base substrate; the black matrix is at one side of the light emitting unit away from the light emitting side of the WOLED front light source; and an orthographic projection of the light emitting unit to the base substrate is completely within an orthographic projection of the black matrix to the base substrate.

Optionally, there is a plurality of pixel units in a display region of the reflective display panel; and one of the light transmission regions faces at least one pixel unit.

Optionally, the display region of the reflective display panel includes a pixel region for arranging the pixel units and a non-pixel region surrounding the pixel region; and an orthographic projection of the light emitting unit to the reflective display panel is within the non-pixel region.

Optionally, the first electrode layer includes a first transparent electrode layer, and the first transparent electrode layer includes a plurality of independent electrode blocks; and the electrode blocks are re-used as touch electrodes.

Optionally, each electrode block is a grid-like structure.

Optionally, each electrode block is a transparent layer without an opening.

Optionally, the light emitting unit of includes a plurality of strips, and regions between the strips define light transmission regions.

Optionally, there is a plurality of pixel units in a display region of the reflective display panel; and one of the light transmission regions faces at least one pixel unit.

Optionally, the reflective display panel is an interference reflective MEMS display panel.

Optionally, the interference reflective MEMS display panel includes a base substrate, a MEMS display unit on the base substrate, and a thin film transistor array layer; the MEMS display unit includes a reflective electrode layer, an air gap, a movable mirror, a dielectric layer and an opposite electrode layer; the movable mirror is disposed in the air gap; when the reflective electrode layer and the opposite electrode layer are electrified, the movable mirror moves upwardly or downwardly according to different voltages.

Optionally, the reflective display device further includes: a photosensitive device configured to sense brightness of ambient light; and a controller configured to, according to the brightness of ambient light sensed by the photosensitive device, control on or off of the WOLED front light source.

Optionally, the reflective display device is a wearable display device.

### BRIEF DESCRIPTION OF THE DRAWINGS

A brief introduction will be given hereinafter to the accompanying drawings which will be used in the description of the embodiments in order to explain the embodiments of the present disclosure more clearly. Apparently, the drawings in the description below are merely for illustrating some embodiments of the present disclosure. Those skilled in the art may obtain other drawings according to these drawings without paying any creative labor.

FIG. 1 is a schematic view of a reflective display device according to some embodiments of the present disclosure;

FIG. 2 is a schematic view of an arrangement mode of a light emitting layer of a WOLED front light source according to some embodiments of the present disclosure;

FIG. 3 is another schematic view of an arrangement mode of a light emitting layer of a WOLED front light source according to some embodiments of the present disclosure;

FIG. 4 is a cross-sectional view of a WOLED front light source according to some embodiments of the present disclosure;

FIG. 5 is a cross-sectional view of a WOLED front light source according to some embodiments of the present disclosure;

FIG. 6 is a top view of touch electrodes of a WOLED front light source according to some embodiments of the present disclosure;

FIG. 7 is a schematic view of a reflective display device according to some embodiments of the present disclosure;

FIG. 8 is a schematic view of an interference reflective MEMS display panel according to some embodiments of the present disclosure;

FIG. 9 is a schematic diagram of working principle of the interference reflective MEMS display panel according to some embodiments of the present disclosure;

FIG. 10 is a schematic view of a thin film transistor array layer of a reflective display panel according to some embodiments of the present disclosure;

FIG. 11 is a flow chart of a method for manufacturing a reflective display device according to some embodiments of the present disclosure; and

FIG. 12 is a flow chart of a method for manufacturing a reflective display device according to some embodiments of the present disclosure.

### DETAILED DESCRIPTION

In order to make objectives, technical solutions and advantages of the present disclosure more clear, the present disclosure will be described in detail with reference to the accompanying drawings. It is apparent that, the described embodiments are only a part of but not all of the embodiments of the present disclosure. Based on the embodiments of the present disclosure, other embodiments obtained without paying any creative labor by one of ordinary skill in this art all belong to the protective scope of the present disclosure.

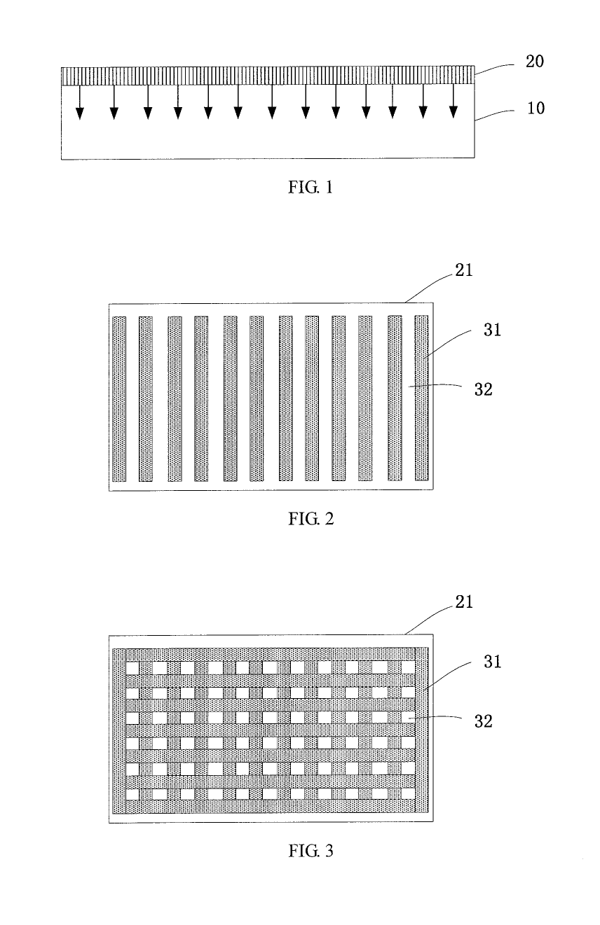

FIG. 1 is a schematic view of a reflective display device according to some embodiments of the present disclosure. Referring to FIG. 1, the reflective display device includes a reflective display panel 10 and a white organic light-emitting diode (WOLED) front light source 20 disposed at a light emitting side of the reflective display panel 10. The WOLED front light source 20 is a single-sided light emitting component, and a light emitting side of the WOLED front light source 20 is oriented towards the reflective display panel 10. A direction of light emitted from the WOLED front light source 20 is a direction of arrows shown in FIG. 1.

In some embodiments of the present disclosure, the WOLED front light source 20 is disposed at the light emitting side of the reflective display panel. In a bright environment, the WOLED front light source 20 may be turned off. Ambient light passes through the WOLED front light source and is incident into the reflective display panel, and then is reflected in the reflective display panel to form a displayed image. In an environment with low ambient light or in a dark environment, the WOLED front light source 20 may be turned on for auxiliary lighting. Light emitted from the WOLED front light source is incident unidirectionally into the reflective display panel, and then is reflected in the reflective display panel to form a displayed image. Since the WOLED front light source is a single-sided light emitting component and emits light that is transmitted in a single direction towards the reflective display panel and is not directly incident to the human eyes, the contrast of the reflective display device can be improved.

Through experimental tests, the contrast of the reflective display device with the WOLED front light source may reach or exceed 20:1, which is far greater than that of the reflective display device with the front light source in form of light guide plate structure in the related art. Further, since the WOLED front light source is self-illuminating without an additional light source for providing light, it facilitates realization of a narrow border; while the front light source in form of light guide plate structure in the related art requires an additional side light source for providing light to the light guide plate structure, and this is not conducive to achieve a narrow border.

In some embodiments of the present disclosure, the WOLED front light source may be directly attached to a light emitting surface of the reflective display panel by means of optically clear adhesive (OCA) or pressure sensitive adhesive (PSA). Of course, in some embodiments, the WOLED front light source may be directly formed at the reflective display panel. For example, a substrate at the light emitting side of the reflective display panel may be re-used as a base substrate, and a variety of layers of the WOLED front light source are formed on the base substrate.

In some embodiments of the present disclosure, the WOLED front light source may include a base substrate, a first electrode layer, a light emitting layer and a second electrode layer. The first electrode layer, the light emitting layer and the second electrode layer are disposed on the base substrate. The light emitting layer is between the first electrode layer and the second electrode layer. Orthographic projections of parts of the first electrode layer, the light emitting layer and the second electrode layer to the base substrate completely overlap each other, and these parts of the first electrode layer, the light emitting layer and the second electrode layer together from a light emitting unit. One of the first electrode layer and the second electrode layer is taken as an anode of the WOLED front light source, and the other one of the first electrode layer and the second electrode layer is taken as a cathode of the WOLED front light source. After the first electrode layer and the second electrode layer are electrified, the light emitting layer can emit white light. The light emitting layer may include only one organic light emitting layer that can emit white light, or may include at least two organic light emitting layers that can emit light of at least two colors, and the light emitted from the at least two organic light emitting layers can be mixed to form white light.

In some embodiments of the present disclosure, the WOLED front light source is disposed at the light emitting surface of the reflective display panel, and the light emitting unit of the WOLED front light source does not cover the entire light emitting surface of the reflective display panel. Some regions of the light emitting surface of the reflective display panel are occupied by the light emitting unit of the WOLED front light source, and other regions of the light emitting surface of the reflective display panel are light transmission regions for allowing light to enter into the reflective display panel and allowing light reflected by the reflective display panel to emit out.

In some embodiments of the present disclosure, the light emitting unit of the WOLED front light source may adopt a variety of arrangement modes. For example, in some embodiments, as shown in FIG. 2, the light emitting unit 31 of the WOLED front light source may have a strip shape. Regions between the strip-shaped light emitting units 31 define light transmission regions. The reference number 2 in FIG. 2 represents a base substrate of the WOLED front light source. In other embodiments, as shown in FIG. 3, the light emitting unit 31 of the WOLED front light source may be a grid-like structure. The grid-like light emitting unit 31 defines a plurality of light transmission regions 32. The reference number 21 in FIG. 3 represents a base substrate of the WOLED front light source. In the embodiment as shown in FIG. 3, the grid-like light emitting unit 31 includes vertical portions and horizontal portions crossing the vertical portions, and the light transmission regions 32 have a square shape or a rectangular shape. Of course, in other embodiments of the present disclosure, the grid-like light emitting unit 31 includes first inclined portions and second inclined portions crossing the first inclined portions, and the light transmission regions 32 have a diamond shape.

In some embodiments of the present disclosure, there is a plurality of pixel units for displaying in a display region of the reflective display panel. Each pixel unit includes a plurality of sub-pixel units, such as three sub-pixel units including red (R), green (G) and blue (B) sub-pixel units. Optionally, one light transmission region of the WOLED front light source faces at least one pixel unit. Optionally, one light transmission region faces more than one pixel units, for example, the light transmission region may face four or nine pixel units.

In some embodiments of the present disclosure, the display region of the reflective display panel includes a pixel region for arranging the pixel units and a non-pixel region surrounding the pixel region. The non-pixel region is usually an opaque region for arranging gate lines and data lines. An orthographic projection of the light emitting unit to the reflective display panel is within the non-pixel region. In other words, the light emitting unit does not block the pixel region of the reflective display panel, and the does not affect displaying of the reflective display panel.

In some embodiments of the present disclosure, in order to enable the WOLED front light source to work as a single-sided light emitting component, one of the first electrode layer and the second electrode layer of the WOLED front light source may be a transparent electrode layer, and may be made of material such as indium tin oxide (ITO) and indium zinc oxide (IZO). The other one of the first electrode layer and the second electrode layer of the WOLED front light source may be an opaque electrode layer, and may be made of material such as metal or metal alloy material.

In some embodiments of the present disclosure, a black matrix may be provided at the WOLED front light source to enable the WOLED front light source to work as a single-sided light emitting component. In other words, the WOLED front light source may further include a black matrix on the base substrate. The black matrix may be at one side of the light emitting unit, and the one side of the light emitting unit is away from the light emitting side of the WOLED front light source. An orthographic projection of the light emitting unit to the base substrate of the WOLED front light source is completely within an orthographic projection of the black matrix to the base substrate of the WOLED front light source. In other words, the black matrix and the light emitting unit are superimposed over each other, a width of the black matrix is greater than or equal to a width of the light emitting unit, so that the black matrix can block the light emitted from the light emitting unit to prevent light from emitting outside from a non-light-emitting side of the WOLED front light source. In some embodiments of the present disclosure, optionally, the black matrix has a width in a range of from 5 μm to 30 μm. The black matrix cannot be too thin, otherwise it is difficult to block the light emitting unit the light unit, thereby affecting lighting effect. The black matrix cannot be too wide, otherwise the black matrix is visible to the human eyes, thereby affecting lighting effect.

Further, optionally, the orthographic projection of the light emitting unit to the base substrate is completely overlaps the orthographic projection of the black matrix to the base substrate. In other words, the black matrix and the light emitting unit have the same shape and overlap with each other.

Structures of the WOLED front light source of some embodiments of the present disclosure are illustrated in conjunctions with examples.

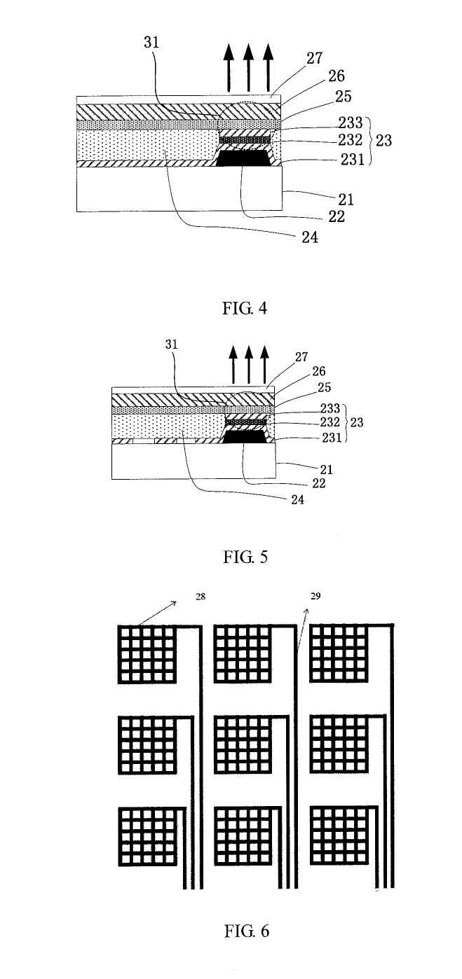

FIG. 4 is a cross-sectional view of a WOLED front light source according to some embodiments of the present disclosure. Referring to FIG. 4, the WOLED front light source includes a base substrate 21, a black matrix 22, a first electrode layer 23, a planarization layer 24, a light emitting layer 25, a second electrode layer 26 and an encapsulation layer 27. The first electrode layer 23 is a composite electrode layer which includes a first transparent electrode layer 231, a metal electrode layer 232 and a second transparent electrode layer 233. The first transparent electrode layer 231 and the second transparent electrode layer 233 may be made of transparent conductive material such as indium tin oxide (ITO) and indium zinc oxide (IZO). The metal electrode layer 232 may be made of metal or metal alloy material with low impedance, such as Ag, Cu and Al. The first transparent electrode layer 231 and the second transparent electrode layer 233 are at two opposite sides of the metal electrode layer 232, and can protect the metal electrode layer 232 to avoid oxidation of the metal electrode layer 232. The first transparent electrode layer 231 may be a whole layer. The second electrode layer 26 may be made of transparent conductive material such as indium tin oxide (ITO) and indium zinc oxide (IZO). The second electrode layer 26 may be a whole layer. Orthographic projections of parts of the first electrode layer 23 the light emitting layer 25 and the second electrode layer 26 to the base substrate 21 overlap each other, and these parts of the first electrode layer 23, the light emitting layer 25 and the second electrode layer 26 together from a light emitting unit 31. An orthographic projection of the light emitting unit 31 to the base substrate 21 is completely within an orthographic projection of the black matrix 22 to the base substrate 21. The planarization layer 24 may be made of resin and the like. The encapsulation layer 27 may be a film packaging layer or a glass packaging layer. In some embodiments of the present disclosure, the WOLED front light source may be a top emission OLED device. A direction of light emitted from the WOLED front light source is a direction of arrows shown in FIG. 4. Of course, in other embodiments of the present disclosure, the WOLED front light source may be a bottom emission OLED device.

In some embodiments of the present disclosure, touch electrodes may be integrated to the WOLED front light source, thereby eliminating the need for a separate touch panel and then reducing the thickness of the reflective display device.

Further, optionally, the first electrode layer or the second electrode layer of the WOLED front light source may be re-used as the touch electrodes, thereby reducing the quantity of mask plates and reducing the thickness of the WOLED front light source.

In some embodiments of the present disclosure, the first electrode layer includes a first transparent electrode layer, and the first transparent electrode layer includes a plurality of independent electrode blocks. The electrode blocks are re-used as the touch electrodes. The first electrode layer may be a cathode or an anode. The first electrode layer may include other conductive layers in addition to the first transparent electrode layer. In other words, the first electrode layer may be a composite electrode layer.

FIG. 5 is a cross-sectional view of a WOLED front light source according to some embodiments of the present disclosure. Referring to FIG. 5, the difference between the embodiment shown in FIG. 5 and the embodiment shown in FIG. 4 lies in that the first transparent electrode layer 231 is cut into a plurality of independent electrode blocks, and the electrode blocks are re-used as the touch electrodes.

FIG. 6 is a top view of touch electrodes of a WOLED front light source according to some embodiments of the present disclosure. As can be seen from FIG. 6, the first transparent electrode layer in form of a whole layer is divided into a plurality of independent electrode blocks 28, and the electrode blocks 28 are re-used as the touch electrodes. In addition, the WOLED front light source according to some embodiments of the present disclosure further includes touch electrode wires 29. The touch electrode wires 29 may adopt a composite electrode layer which is the same as the first electrode layer 23. In other words, the ouch electrode wire 29 may also include three layers including the first transparent electrode layer 231, the metal electrode layer 232 and the second transparent electrode layer 233. In some embodiments of the present disclosure, optionally, each electrode block 28 is a grid-like structure. The grid-like electrode block 28 can expose the pixel region of the reflective display panel, thereby improving transmittance and brightness. Of course, in other embodiments of the present disclosure, since the electrode block 28 is transparent, the electrode block 28 may be a whole layer. In other words, the electrode block 28 may be a transparent layer without an opening.

The structures of the WOLED front light source are described above with examples. Structures of the reflective display panel are described in details hereinafter.

The reflective display panel of some embodiments of the present disclosure may be display panels of different types, such as reflective liquid crystal display panel, reflective electronic ink display panel and reflective micro-electro-mechanical system (MEMS) display panel.

In an optional embodiment of the present disclosure, the reflective display panel may be an interference reflective MEMS display panel based on interference effects in physics. A basic display unit of the interference reflective MEMS display panel includes a micro mechanical structure which includes a reflective electrode layer, an absorption metal layer and an air gap switching between the reflective electrode layer and the absorption metal layer, adjusts a thickness of the air gap by adjusting a position of a transflective movable mirror, adjust displayed color by means of stationary wave absorption formed by light reflected by the reflective electrode layer and light reflected by the movable mirror, thereby realizing reflective color display.

In some optional embodiments of the present disclosure, the interference reflective MEMS display panel may include a base substrate, a MEMS display unit on the base substrate, and a thin film transistor array layer for controlling the MEMS display unit. The MEMS display unit includes a reflective electrode layer, an air gap, a transflective movable mirror, a dielectric layer and an opposite electrode layer. The transflective movable mirror is disposed in the air gap. When the reflective electrode layer and the opposite electrode layer are electrified, the transflective movable mirror can move upwardly or downwardly according to different voltages.

In some optional embodiments of the present disclosure, the thin film transistor array layer may be disposed between the MEMS display unit and the base substrate, or may be disposed at one side of the MEMS display unit away from the base substrate.

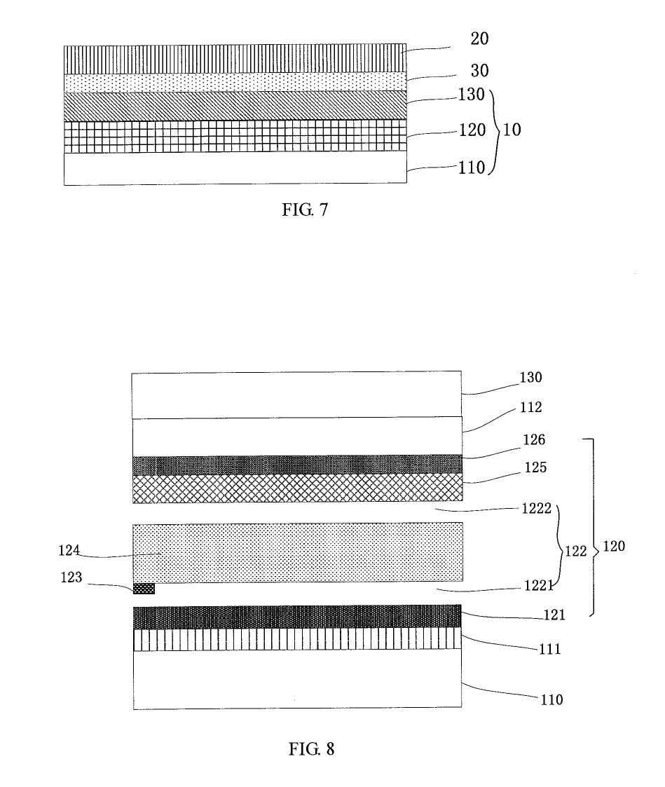

FIG. 7 is a schematic view of a reflective display device according to some embodiments of the present disclosure. Referring to FIG. 7, the reflective display device includes an interference reflective MEMS display panel 10 and a WOLED front light source 20. The WOLED front light source 20 is attached to a light emitting surface of the interference reflective MEMS display panel 10 by means of optically clear adhesive 30. The interference reflective MEMS display panel 10 includes a base substrate 110, a MEMS display unit 120 on the base substrate 110, and a thin film transistor array layer 130.

FIG. 8 is a schematic view of an interference reflective MEMS display panel according to some embodiments of the present disclosure. Referring to FIG. 8, the interference reflective MEMS display panel includes a base substrate 110, a buffer layer 111, a MEMS display unit 120, a planarization layer 112 and a thin film transistor array layer 130. The MEMS display unit 120 includes a reflective electrode layer 121, an air gap 122, a spacer 123, a movable mirror 124, a dielectric layer 125 and an opposite electrode layer 126. The buffer layer 111 may be made of insulating material such as SiO₂. The buffer layer 111 has a certain thickness so as to obtain better evenness. The reflective electrode layer 121 may be made of metal or metal alloy, such as Mo or MoCr. The reflective electrode layer 121 is used as one electrode of the MEMS display unit 120. The reflective electrode layer 121 is also used as a reflective layer for reflecting light entering into the MEMS display unit 120 to form reflection light. The movable mirror 124 is a transflective movable mirror disposed in the air gap 122, and is capable of moving upwardly or downwardly in the air gap 122. The movable mirror 124 divides the air gap 122 into two portions including an upper air gap 1222 and a lower air gap 1221. The air gap 122 may be prepared by means of semiconductor sacrificial layer process. Specifically, a sacrificial layer may be first prepared; after competition of the subsequent film processes, the sacrificial layer is etched by gas aching (dry etching) process, thereby forming the air gap 122. The movable mirror 124 has a certain transmittance and a certain mechanical strength. The movable mirror 124 may be a composite layer, for example, the movable mirror 124 may be composed of a thin metal layer and a transparent oxide metal layer superimposed on the thin metal layer. Since the thin metal layer is thinner, the thin metal layer has a certain transmittance and does not affect light transmission. The thin metal layer may be made of metal or metal alloy, such as Al or an alloy of Al and Cu. The transparent oxide metal layer has a high transmittance, and may be prepared by mixing Zirconia (ZrO) and SiO₂. In addition, in order to prevent the movable mirror 124 from colliding with the reflective electrode layer 121 when the movable mirror 124 moves, a spacer 123 is disposed at a surface of the movable mirror 124 facing the reflective electrode layer 121. The spacer 123 may be made of soft insulating material such as resin. Of course, another spacer 123 may further be disposed at a surface of the movable mirror 124 facing the dielectric layer 125. The dielectric layer 125 may be made of insulating material such as SiO₂. The opposite electrode layer 126 may be made of metal or metal alloy, such as an alloy of Al and Nd. The opposite electrode layer 126 is at the non-pixel region of the reflective display panel, and is not disposed in the pixel region to avoid affecting light transmission. The planarization layer 112 may be made of insulating material such as SiO₂, and may be taken as a buffer layer of the thin film transistor array layer 130.

In some optional embodiments of the present disclosure, when the reflective electrode layer 121 and the opposite electrode layer 126 are electrified, the movable mirror 124 moves upwardly or downwardly in the air gap 122. According to the principle that like charges repel each other while opposite charges attract, the movement of the movable mirror 124 is controlled by supplying different charges to upper and lower electrodes. Light incident to the air gap 122 will interfere with reflection light reflected by the reflective electrode layer 121. When the movable mirror 124 moves upwardly until the thickness of the upper air gap 1222 is zero, the MEMS display unit 120 display black according to the principle of stationary wave interference cancellation. When the movable mirror 124 moves downwardly and then the thickness of the upper air gap 1222 is increased, the MEMS display unit 120 display different colors such as one of red, green and blue, according to different thickness of the upper air gap 1222.

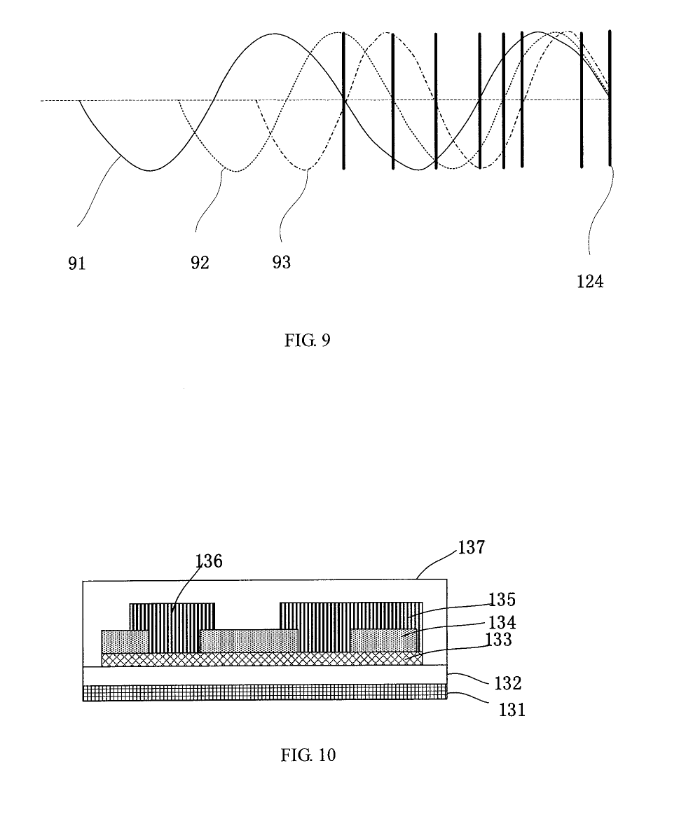

FIG. 9 is a schematic diagram of working principle of the interference reflective MEMS display panel according to some embodiments of the present disclosure. Referring to FIG. 9, reference numbers 91, 92, 93 represent stationary waves formed by incident light and reflection light. Different stationary waves are corresponding to different colors. The reference number 91 is corresponding to red; the reference number 92 is corresponding to green, and the reference number 93 is corresponding to blue. As can be seen from FIG. 9, different positions of the movable mirror 124 are corresponding to different stationary waves, and then the MEMS display unit 120 display different colors accordingly.

Working process of the above reflective display device is described below. In a bright environment, the WOLED front light source is turned off. Ambient light passes through the WOLED front light source and the thin film transistor array layer and is incident into the reflective electrode layer 121 of the MEMS display unit and then is reflected by the reflective electrode layer 121, then the incident ambient light interferes with the reflection light to form a stationary wave. By adjusting the thickness of the upper air gap 1222, color light is formed. The color light passes through the thin film transistor array layer and the WOLED front light source and then is observed by the human eyes. In a dark environment, the WOLED front light source is turned on for auxiliary lighting. Light emitted from the WOLED front light source is incident unidirectionally downwardly and passes through the thin film transistor array layer, and then is reflected by the reflective electrode layer 121 of the MEMS display unit, then the incident light interferes with the reflection light to form a stationary wave. By adjusting the thickness of the upper air gap 1222, color light is formed. The color light passes through the thin film transistor array layer and the WOLED front light source and then is observed by the human eyes.

In some optional embodiments of the present disclosure, thin film transistors in the thin film transistor array layer of the reflective display panel may be top-gate thin film transistors, bottom-gate thin film transistors, etch-blocking type thin film transistors, or back channel type thin film transistors. The thin film transistor mainly includes a gate electrode, a gate metal layer, an active layer, a source electrode and a drain electrode.

FIG. 10 is a schematic view of a thin film transistor array layer of a reflective display panel according to some embodiments of the present disclosure. Referring to FIG. 10, the thin film transistor array layer includes a gate electrode 131, a gate insulation layer 132, an active layer 133, an etching stop layer 134, a source electrode 135, a drain electrode 136 and a passivation layer 137. The active layer 133 may be made of semiconductor material such as oxide semiconductor (i.e., IGZO), or low temperature poly-silicon semiconductor.

In some embodiments of the present disclosure, the reflective display device may further include a controller for controlling on or off of the WOLED front light source. Optionally, in some optional embodiments of the present disclosure, the reflective display device may further include a photosensitive device for sensing brightness of ambient light. The controller is configured to, according to the brightness of ambient light sensed by the photosensitive device, control on or off of the WOLED front light source. In some embodiments, the controller may be implemented by a processor, and the photosensitive device may be implemented by a light sensor.

Of course, in some embodiments of the present disclosure, turning on or off of the WOLED front light source may be manually controlled. For example, a button may be provided at the reflective display device and may be coupled to the controller. When pressing the button, a control signal is generated, and the controller controls on or off of the WOLED front light source according to the control signal.

The reflective display device of the above embodiments of the present disclosure may be a wearable display device.

FIG. 11 is a flow chart of a method for manufacturing a reflective display device according to some embodiments of the present disclosure. Referring to FIG. 11, the method includes the following steps S11 to S13.

The step S11 is to form a reflective display panel.

The step S12 is to form a WOLED front light source.

The step S13 is to attach the WOLED front light source to a light emitting side of the reflective display panel. The WOLED front light source is a single-sided light emitting component, and a light emitting side of the WOLED front light source is oriented towards the reflective display panel.

In the reflective display device manufactured according to some embodiments of the present disclosure, the WOLED front light source is disposed at the light emitting side of the reflective display panel. In a bright environment, the WOLED front light source may be turned off. Ambient light passes through the WOLED front light source and is incident into the reflective display panel, and then is reflected in the reflective display panel to form a displayed image. In an environment with low ambient light or in a dark environment, the WOLED front light source may be turned on for auxiliary lighting. Light emitted from the WOLED front light source is incident unidirectionally into the reflective display panel, and then is reflected in the reflective display panel to form a displayed image. Since the WOLED front light source is a single-sided light emitting component and emits light that is transmitted in a single direction towards the reflective display panel and is not directly incident to the human eyes, the contrast of the reflective display device can be improved. Further, since the WOLED front light source is self-illuminating without an additional light source for providing light, it facilitates realization of a narrow border; while the front light source in form of light guide plate structure in the related art requires an additional side light source for providing light to the light guide plate structure, and this is not conducive to achieve a narrow border.

Optionally, the formed WOLED front light source includes a base substrate, a first electrode layer, a light emitting layer and a second electrode layer. The first electrode layer, the light emitting layer and the second electrode layer are disposed on the base substrate. Orthographic projections of parts of the first electrode layer, the light emitting layer and the second electrode layer to the base substrate completely overlap each other, and these parts of the first electrode layer, the light emitting layer and the second electrode layer together from a light emitting unit. The light emitting unit may be a grid-like structure. The grid-like light emitting unit defines a plurality of light transmission regions.

Optionally, the formed WOLED front light source further includes a black matrix at the base substrate. The black matrix is disposed at one side of the light emitting unit away from the light emitting side of the WOLED front light source. An orthographic projection of the light emitting unit to the base substrate is completely within an orthographic projection of the black matrix to the base substrate.

Optionally, there is a plurality of pixel units in a display region of the formed reflective display panel, and one light transmission region faces at least one pixel unit.

Optionally, the display region of the formed reflective display panel includes a pixel region for arranging the pixel units and a non-pixel region surrounding the pixel region. An orthographic projection of the light emitting unit to the reflective display panel is within the non-pixel region.

Optionally, the first electrode layer includes a first transparent electrode layer, and the first transparent electrode layer includes a plurality of independent electrode blocks. The electrode blocks are re-used as the touch electrodes.

Optionally, the reflective display panel may be an interference reflective MEMS display panel.

Optionally, the interference reflective MEMS display panel may include a base substrate, a MEMS display unit on the base substrate, and a thin film transistor array layer. The MEMS display unit includes a reflective electrode layer, an air gap, a movable mirror, a dielectric layer and an opposite electrode layer. The movable mirror is disposed in the air gap. When the reflective electrode layer and the opposite electrode layer are electrified, the movable mirror can move upwardly or downwardly according to different voltages.

The method for manufacturing a reflective display device according to some embodiments of the present disclosure are described in details in conjunction with embodiments hereinafter.

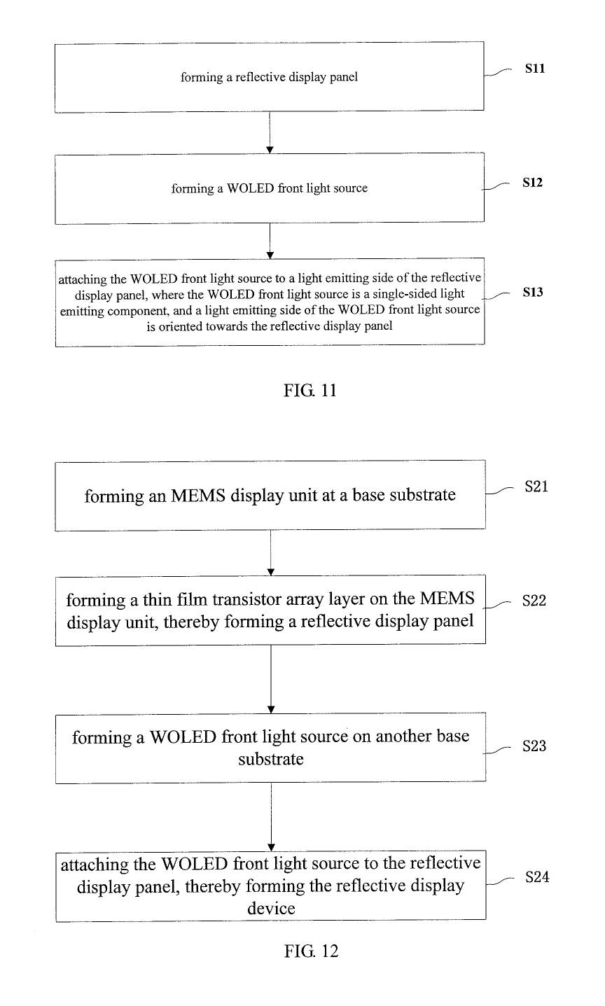

FIG. 12 is a flow chart of a method for manufacturing a reflective display device according to some embodiments of the present disclosure. Referring to FIG. 12, the method includes the following steps S21 to S24.

The step S21 is to form an MEMS display unit at a base substrate.

The step S22 is to form a thin film transistor array layer on the MEMS display unit, thereby forming a reflective display panel.

The step S23 is to form a WOLED front light source on another base substrate.

The step S24 is to attach the WOLED front light source to the reflective display panel, thereby forming the reflective display device.

Unless otherwise defined, any technical or scientific terms used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than being limited to physical or mechanical connection. Such words as “on/above”, “under/below”, “left” and “right” are merely used to represent relative position relationship, and when an absolute position of an object is changed, the relative position relationship will be changed too.

The above are merely the preferred embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

What is claimed is:

1. A reflective display device comprising:
a reflective display panel; and
a white organic light-emitting diode (WOLED) front light source at a light emitting side of the reflective display panel;
wherein the WOLED front light source is a single-sided light emitting component, and a light emitting side of the WOLED front light source is oriented towards the reflective display panel.

2. The reflective display device of claim 1, wherein the WOLED front light source includes a base substrate, a first electrode layer, a light emitting layer and a second electrode layer; the first electrode layer, the light emitting layer and the second electrode layer are disposed on the base substrate; and
wherein orthographic projections of parts of the first electrode layer, the light emitting layer and the second electrode layer to the base substrate completely overlap each other, and these parts of the first electrode layer, the light emitting layer and the second electrode layer together from a light emitting unit.

3. The reflective display device of claim 2, wherein the light emitting unit is a grid-like structure, and the grid-like light emitting unit defines a plurality of light transmission regions.

4. The reflective display device of claim 2, wherein each of the light transmission regions has a square shape or a rectangular shape.

5. The reflective display device of claim 2, wherein each of the light transmission regions has a diamond shape.

6. The reflective display device of claim 2, wherein the WOLED front light source further includes a black matrix on the base substrate; the black matrix is at one side of the light emitting unit away from the light emitting side of the WOLED front light source; and an orthographic projection of the light emitting unit to the base substrate is completely within an orthographic projection of the black matrix to the base substrate.

7. The reflective display device of claim 3, wherein there is a plurality of pixel units in a display region of the reflective display panel; and one of the light transmission regions faces at least one pixel unit.

8. The reflective display device of claim 7, wherein the display region of the reflective display panel includes a pixel region for arranging the pixel units and a non-pixel region surrounding the pixel region; and an orthographic projection of the light emitting unit to the reflective display panel is within the non-pixel region.

9. The reflective display device of claim 3, wherein the first electrode layer includes a first transparent electrode layer, and the first transparent electrode layer includes a plurality of independent electrode blocks; and the electrode blocks are re-used as touch electrodes.

10. The reflective display device of claim 9, wherein each electrode block is a grid-like structure.

11. The reflective display device of claim 9, wherein each electrode block is a transparent layer without an opening.

12. The reflective display device of claim 2, wherein the light emitting unit of includes a plurality of strips, and regions between the strips define light transmission regions.

13. The reflective display device of claim 12, wherein there is a plurality of pixel units in a display region of the reflective display panel; and one of the light transmission regions faces at least one pixel unit.

14. The reflective display device of claim 12, wherein the reflective display panel is an interference reflective MEMS display panel.

15. The reflective display device of claim 14, wherein the interference reflective MEMS display panel includes a base substrate, a MEMS display unit on the base substrate, and a thin film transistor array layer; the MEMS display unit includes a reflective electrode layer, an air gap, a movable mirror, a dielectric layer and an opposite electrode layer; the movable mirror is disposed in the air gap; when the reflective electrode layer and the opposite electrode layer are electrified, the movable mirror moves upwardly or downwardly according to different voltages.

16. The reflective display device of claim 1, further comprising:
a photosensitive device configured to sense brightness of ambient light; and
a controller configured to, according to the brightness of ambient light sensed by the photosensitive device, control on or off of the WOLED front light source.

17. The reflective display device of claim 1, wherein the reflective display device is a wearable display device.
